(19) United States
(12) Patent Application Publication
(10) Pub. No.: US 2013/0273745 A1
(43) Pub. Date: Oct. 17, 2013

(54) ETCHING PASTE, PRODUCTION METHOD THEREOF, AND PATTERN FORMING METHOD USING THE SAME

(71) Applicant: Jae Joon SHIM, Uiwang-si (KR)

(72) Inventor: Jae Joon SHIM, Uiwang-si (KR)

(21) Appl. No.: 13/912,314

(22) Filed: Jun. 7, 2013

Related U.S. Application Data
(63) Continuation of application No. PCT/KR2011/001695, filed on Mar. 11, 2011.

(30) Foreign Application Priority Data
Dec. 15, 2010 (KR) 10-2010-0128661

(51) Int. Cl. C09K 13/06; H01L 21/306

(52) U.S. Cl. CPC C09K 13/06; H01L 21/30604
USPC 438/754; 252/79.4

(57) ABSTRACT

An etching paste and a method of forming a pattern, the etching paste including an organic binder; phosphoric acid; a nitrogen-containing compound; and a solvent, the nitrogen-containing compound including at least one selected from amine compounds represented by Formula 1 and ammonium compounds represented by Formula 2.

### CROSS-REFERENCE TO RELATED APPLICATIONS

This application is a continuation of pending International Application No. PCT/KR2011/001695, entitled “Etching Paste, A Production Method Thereof, and A Pattern Forming Method Using the Same,” which was filed on Mar. 11, 2011, the entire contents of which are hereby incorporated by reference.

Korean Patent Application No. 10-2010-0128661, filed on December 15, 2010, in the Korean Intellectual Property Office, and entitled: “Etching Paste, A Production Method Thereof, and A Pattern Forming Method Using the Same,” is incorporated by reference herein in its entirety.

### BACKGROUND

1. Field

Embodiments relate to an etching paste, a method of preparing the same, and a method of forming a pattern using the same.

2. Description of the Related Art

A pattern forming process may be used for semiconductor devices and flat panel displays, e.g., LCDs, OLEDs, and PDPs. A pattern forming process may be performed using a photosensitive material, e.g., photoresist, in which a photoresist layer is formed by depositing the photoresist on a metal layer formed on a substrate of an insulating material, e.g., glass, or a semiconductor material, followed by exposure and development through a photo mask. Then, only the metal layer may be etched using an etching solution, and the photoresist pattern may be removed using a stripper. Thus, only a metal pattern may remain on the substrate, thereby forming a pattern.

### SUMMARY

Embodiments are directed to an etching paste, a method of preparing the same, and a method of forming a pattern using the same

The embodiments may be realized by providing an etching paste including an organic binder; phosphoric acid; a nitrogen-containing compound; and a solvent, the nitrogen-containing compound including at least one selected from amine compounds represented by Formula 1 and ammonium compounds represented by Formula 2:

(R)ₙ—N—Hₘ, [Formula 1]

wherein, in Formula 1, R is a C1 to C12 alkyl group or a C6 to C12 substituted or unsubstituted aryl group; n is an integer from 1 to 3; m is an integer from 0 to 2; and n+m is 3,

(NH₄⁺)ₖX, [Formula 2]

wherein, in Formula 2, X is a carbonate anion, a hydroxide anion, or a carbamate anion, and k is 1 or 2.

The organic binder may be a water-soluble polymer.

The organic binder may include at least one selected from the group of cellulose resins, xanthan gum, polyvinylpyrrolidone, polyvinyl alcohol, water-soluble (meth)acrylic resins, polyether-polyol, and poly(ether urea)-polyurethane.

The nitrogen-containing compound may include at least one selected from the group of methylamine, ethylamine, propylamine, butylamine, dodecylamine, benzylamine, ammonium hydroxide, ammonium carbonate, and ammonium carbamate.

A mole ratio of the nitrogen-containing compound to the phosphoric acid may range from 1:1 to 1.5:1.

The etching paste may include 3 to 20 wt % of the organic binder, 15 to 50 wt % of the phosphoric acid, 0.5 to 20 wt % of the nitrogen-containing compound, and a balance of the solvent.

The etching paste may further include an additive selected from the group of organic acid, inorganic particles, foaming agents, surfactants, leveling agents, antifoaming agents, thickeners, thixotropic agents, plasticizers, dispersants, viscosity stabilizers, UV stabilizers, antioxidants, and coupling agents.

The etching paste may have a viscosity of 5,000 cP·s to 30,000 cP·s.

The etching paste may be for etching a target material on a substrate by printing the etching paste in a predetermined pattern on the target material, the target material including aluminum, ITO, or ATO.

The embodiments may also be realized by providing a method of forming a pattern, the method including printing the etching paste according to an embodiment on a substrate on which an etching target is deposited; drying the etching paste; and washing the etching paste with water to form a pattern.

The etching target may be a metal or a metal compound.

The organic binder may be a water-soluble polymer.

The organic binder may include at least one selected from the group of cellulose resins, xanthan gum, polyvinylpyrrolidone, polyvinyl alcohol, water-soluble (meth)acrylic resins, polyether-polyol, and poly(ether urea)-polyurethane.

The nitrogen-containing compound may include at least one selected from the group of methylamine, ethylamine, propylamine, butylamine, dodecylamine, benzylamine, ammonium hydroxide, ammonium carbonate, and ammonium carbamate.

A mole ratio of the nitrogen-containing compound to the phosphoric acid may range from 1 to 1.5.

The etching paste may include 3 to 20 wt % of the organic binder, 15 to 50 wt % of the phosphoric acid, 0.5 to 20 wt % of the nitrogen-containing compound, and a balance of the solvent.

The etching paste may further include an additive selected from the group of organic acid, inorganic particles, foaming agents, surfactants, leveling agents, antifoaming agents, thickeners, thixotropic agents, plasticizers, dispersants, viscosity stabilizers, UV stabilizers, antioxidants, and coupling agents.

The etching paste may have a viscosity of 5,000 cP·s to 30,000 cP·s.

Drying the etching paste may include heating at a temperature of 100° C. to 250° C.

Printing the etching paste may include printing the paste in a predetermined pattern on the etching target.

### BRIEF DESCRIPTION OF THE DRAWINGS

Features will become apparent to those of skill in the art by describing in detail exemplary embodiments with reference to the attached drawings in which:

FIG. 1 illustrates stages in a pattern forming process in accordance with an embodiment.

FIG. 2 illustrates a flowchart of the pattern forming process in accordance with an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

An etching paste according to an embodiment may include, e.g., (a) an organic binder; (b) phosphoric acid; (c) a nitrogen-containing compound; and (d) a solvent.

(a) Organic Binder

The organic binder may help enhance viscosity or rheology. In an implementation, the organic binder may be advantageously selected from water soluble polymers.

For example, the organic binder may include cellulose resins including methyl cellulose, ethyl cellulose, hydroxyethyl cellulose, hydroxypropyl cellulose (HPC), carboxymethyl cellulose, sodium carboxymethyl cellulose (CMC-Na), sodium carboxymethyl hydroxyethyl cellulose, nitrocellulose, and the like, xanthan gum, polyvinylpyrrolidone, polyvinyl alcohol, water-soluble (meth)acrylic resins including acrylic polymers obtained by copolymerization of acrylic monomers having a hydrophilic group, such as a hydroxyl group and a carboxyl group, polyether-polyol, and poly(ether urea)-polyurethane, without being limited thereto. The materials may be used alone or in combination of two or more thereof.

The organic binder may be present in the etching paste in an amount of about 3 wt % to about 20 wt %, e.g., 5 wt % to 15 wt %. Within this range of the organic binder, the etching paste may exhibit excellent printability while improving pattern precision.

(b) Phosphoric Acid

The phosphoric acid may react with the nitrogen containing compound, e.g., an amine compound or an ammonium compound, to form a complex, which may be separated at about 100° C. to about 250° C. to have an etching function. Thus, the etching paste may stably and effectively exhibit the etching function. A phosphoric acid having a concentration of about 80% or more may be advantageously used.

The phosphoric acid may be present in the etching paste in an amount of about 15 wt % to about 50 wt %, e.g., from 20 wt % to 45 wt %. Within this range of the phosphoric acid, the etching paste may exhibit excellent etching performance and lessened adverse effects on equipment. In an implementation, the phosphoric acid may be present in an amount of 25 wt % to 45 wt %.

In an implementation, a weight:weight ratio ((b):(c)) of the phosphoric acid (b) to the nitrogen-containing compound (c) may be 5:1 to 15:1, e.g., 5:1 to 10:1. Within this ratio range, the etching paste may exhibit excellent etching performance.

(c) Nitrogen-Containing Compound

The nitrogen-containing compound may include at least one selected from amine compounds and ammonium compounds or salts.

The amine compounds may be represented by Formula 1, below.

(R)ₙ—N—Hₘ [Formula 1]

In Formula 1, R may be a C1 to C12 alkyl group or a C6 to C12 substituted or unsubstituted aryl group; n may be an integer from 1 to 3; m may be an integer from 0 to 2; and n+m is 3.

In an implementation, n may be 1 or 2, and m may be 1 or 2.

Examples of the amine compounds may include methylamine, ethylamine, propylamine, butylamine, dodecylamine, and benzylamine, without being limited thereto. The amines may be used alone or in combination of two or more thereof.

The ammonium compounds may be represented by Formula 2, below.

(NH₄⁺)ₖX [Formula 2]

In Formula 2, X may be a carbonate anion, a hydroxide anion, or a carbamate anion, and k may be 1 or 2.

Examples of the ammonium compounds may include an ammonia water (ammonium hydroxide), ammonium carbonate, and ammonium carbamate, without being limited thereto. The ammonium compounds may be used alone or in combination of two or more thereof.

In an implementation, a mixture of the amine compound and the ammonium compound may be used.

The nitrogen containing compound, e.g., the amine compound and/or the ammonium compound, may react with the phosphoric acid to form a complex, which may be separated at about 100° C. to 250° C. to have an etching function.

A mole ratio of the nitrogen-containing compound to the phosphoric acid may be in the range of, e.g., 1:1 to 1.5:1. Within this range, the etching paste may be neutralized without a decrease in printability. In an implementation, the mole ratio of the nitrogen-containing compound to the phosphoric acid may be 1.1:1 to 1.3:1.

The (c) nitrogen-containing compound may be present in the etching paste in an amount of 0.5 wt % to 20 wt %, e.g., 1 wt % to 15 wt % or 3 wt % to 10 wt %. Within this range, the etching paste may exhibit excellent etching performance and lessened effects on equipment. In an implementation, the (c) nitrogen-containing compound may be present in an amount of 4 wt % to 9.5 wt %.

(d) Solvent

As the solvent, a suitable solvent that does not remarkably reduce water solubility of the etching paste may be used. Examples of the solvent may include water, n-methylpyrrolidone (NMP), ethylene glycol butyl ether, propylene carbonate, ethylene glycol, N-methyl-2-pyridone, ethylene glycol monoacetate, diethylene glycol, diethylene glycol acetate, tetraethylene glycol, propylene glycol, propylene glycol monomethyl ether, trimethylene glycol, glyceryl diacetate, hexylene glycol, dipropyl glycol, oxylene glycol, 1,2,6-hexanetriol, and glycerin, without being limited thereto. The solvents may be used alone or in combination of two or more thereof.

The amount of solvent may be specifically determined in use and may be adjusted to facilitate adjustment of viscosity. In an implementation, the solvent may be present in the etching paste in an amount of 20 wt % to 80 wt %, e.g., 25 wt % to 60 wt % or 25 wt % to 50 wt %.

In an implementation, the etching paste may further include an additive, e.g., in order to improve fluidity, processibility, and stability, as desired. The additive may include, e.g., organic acids, inorganic particles, foaming agents, leveling agents, surfactants, antifoaming agents, thickeners, thixotropic agents, plasticizers, dispersants, viscosity stabilizers, UV stabilizers, antioxidants, coupling agents, or the like. The additives may be used alone or in combination of two or more thereof.

The organic acid may include, e.g., lactic acid, acetic acid, malonic acid, and/or citric acid. When included, the organic acid may be present in the etching paste in an amount of 0.1 wt % to 10 wt %, e.g., 1 wt % to 5 wt %.

The inorganic particles may include, e.g., silica, carbon black, cobalt pigments, iron pigments, and/or titanium dioxide. When included, the inorganic particles may be present in the etching paste in an amount of 1 wt % to 15 wt %, e.g., 5 wt % to 10 wt %.

A method of preparing the etching paste according to an embodiment may include preparing a binder solution by dissolving the (a) organic binder in the (d) solvent; and adding the (b) phosphoric acid and the (c) nitrogen containing compound, e.g., the at least one compound selected from the amine compounds represented by Formula 1 and the ammonium compounds represented by Formula 2, to the solution to react therewith.

The prepared etching paste according to an embodiment may have a viscosity of 5,000 cP·s to 30,000 cP·s at room temperature, e.g., from 10,000 cP·s to 25,000 cP·s. Within this viscosity range, the etching paste facilitates dispersion and may exhibit excellent printability. The viscosity may be measured using a Brookfield viscometer LVDVII+ (#14 spindle, 120 rpm).

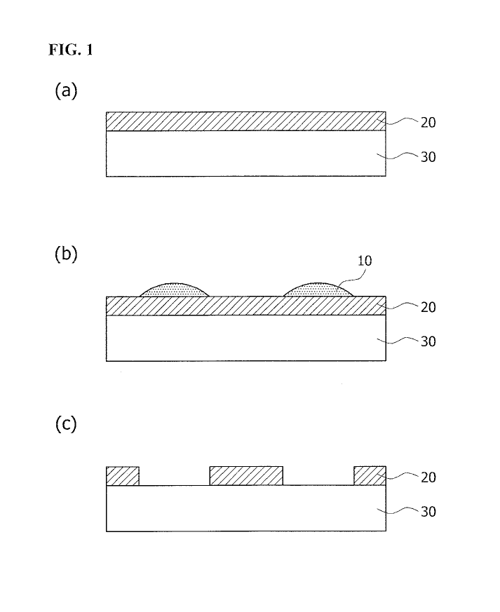

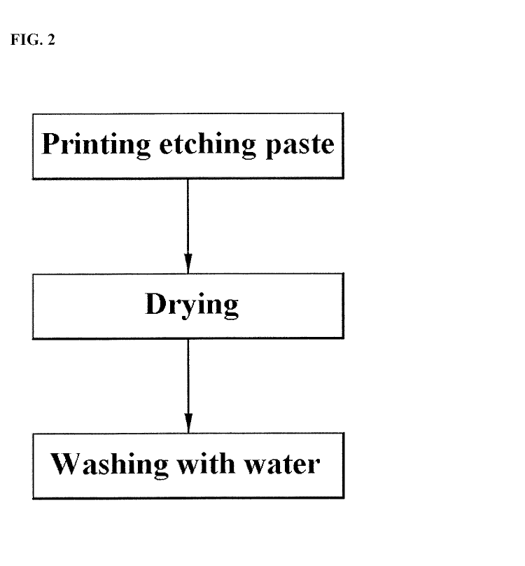

Another embodiment relates to a method of forming a pattern using the etching paste. FIG. 1 illustrates stages in a pattern forming process in accordance with an embodiment. FIG. 2 illustrates a flowchart of the pattern forming process in accordance with the embodiment.

As shown in FIGS. 1 and 2, an etching target 20 may be deposited on a substrate 30 to prepare a substrate 30 on which the etching target 20 is deposited, (Step a). In an implementation, the etching target 20 may be or may include, e.g., a metal or a metal compound. The metal or metal compound may include, e.g., ITO, antimony tin oxide (ATO), aluminum, or the like, without being limited thereto. Deposition may be carried out by, e.g., vacuum deposition using a metal target to deposit the object to several angstroms (Å) to several nanometers (nm).

Then, the etching paste 10 may be printed on the substrate (Step b). In other words, as will be apparent to a person of ordinary skill in the art from the foregoing description and from the drawings the etching paste may be printed in a predetermined pattern, as shown in FIG. 1. The etching paste 10 may be printed by, e.g., screen-printing, offset printing, ink-jet printing, or coating, without being limited thereto.

Then, the printed paste 10 may be dried. Drying may be carried out in a belt type dry oven or a box type dry oven at 100° C. to 250° C. Within this temperature range, the paste may exhibit an etching function while an acid and a complex are separated from each other. In an implementation, the drying temperature may range from 160° C. to 230° C. After drying, the paste 10 may be left at room temperature (˜25° C.) for about 5 to 60 minutes.

Then, the dried paste may be washed, so that the paste may be removed from the substrate 30, and an area where the paste has been placed is etched, thereby forming a pattern (Step c). In an implementation, the paste may be removed by washing with water. In another implementation, the paste may be removed by a developing machine using a developing agent.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Examples 1 to 5 and Comparative Example 1

### Preparation of Etching Paste

Hydroxypropyl cellulose (L-IND, Ashland Inc.) was dissolved in distilled water at 0° C. to 5° C. for 2 hours while stirring at 2,000 rpm, and then heated to room temperature. NMP (Aldrich Co.) was added thereto, thereby preparing an organic binder solution. Then, silica (A200, Degussa GmBH), a foaming agent (Expancel WU40, Akzo Nobel N.V.), acetic acid (Aldrich Co.), and a leveling agent (BYK Chemical Company, BYK-333) were added to the prepared solution, thereby preparing a paste using a bead-mill. A 85% phosphoric acid solution was added dropwise to the paste while stirring the paste, followed by dropwise addition of a nitrogen-containing compound and stirring for 3 hours, thereby producing an etching paste. The respective compositions are listed in Table 1, below.

TABLE 1

| | | | | | | | Comparative |
|---|---|---|---|---|---|---|---|
| | | Example 1 | Example 2 | Example 3 | Example 4 | Example 5 | Example 1 |
| (a) Organic binder | | 5 | 5 | 5 | 5 | 5 | 5 |
| (b) Phosphoric acid | | 42 | 42 | 42 | 42 | 42 | 45.5 |
| (c) | (c1) Methylamine | 4.5 | — | — | — | — | — |
| (c) | (c2) Ammonium | — | 4.5 | — | — | — | — |
| | hydroxide | | | | | | |
| (c) | (c3) Benzylamine | — | — | 4.5 | — | — | — |
| (c) | (c4) Dodecylamine | — | — | — | 4.5 | — | — |
| (c) | (c5) Ammonium | — | — | — | — | 4.5 | — |
| | carbonate | | | | | | |
| (d) | Distilled water | 18.5 | 18.5 | 18.5 | 18.5 | 18.5 | 19.0 |
| (d) | NMP | 18 | 18 | 18 | — | 18 | 18.5 |

| | | | | | | |
|---|---|---|---|---|---|---|
| Acetic acid | 3 | 3 | 3 | 3 | 3 | 3 |
| Silica | 7 | 7 | 7 | 7 | 7 | 7 |
| Foaming agent | 1.1 | 1.1 | 1.1 | 1.1 | 1.1 | 1.1 |
| Leveling agent | 0.9 | 0.9 | 0.9 | 0.9 | 0.9 | 0.9 |

(Unit: percent by weight (wt %))

Metal patterns were formed using the etching pastes obtained in Examples 1 to 5 and Comparative Example 1 as follows.

Formation of Metal Pattern

Each etching paste was printed on an ITO-deposited glass substrate (PD200, Asahi Glass Co.) to a thickness of several angstroms (Å) to several nanometers (nm). Then, the substrate was dried in a belt type dry oven or a box type dry oven at a temperature of 150° C. to 200° C. and then left at room temperature for 20 minutes. Then, the etching paste was removed from the substrate using a developing machine with a developing agent of 0.1% sodium carbonate, thereby forming a pattern. The pattern was evaluated as to printing resolution limit, etching performance, and metal corrosion as follows.

(1) Printing resolution limit: The etching paste was printed on an ITO-deposited glass substrate (PD200, Asahi Glass Co., Ltd.) through a screen mask having a line width of 30 μm to 150 μm. Then, disconnection of a pattern or a pattern not intruding into a non-etched region was expressed as a printing resolution limit.

(2) Etching residue: It was evaluated as to whether the metal layer remained after removal of the etching paste.

(3) Metal corrosion: With a 20 cm diameter glass bottle filled with the etching paste to a height of 2 mm from the bottom thereof, an iron plate (2 cm×2 cm) was suspended in the glass bottle using a holder. Then, the glass bottle was sealed and left at 50° C. for 24 hours, followed by observing the surface of the iron plate. Yellow damage of the plate surface due to oxidation was observed, and a degree of yellow damage was evaluated (Strong; Yellow damage on the overall surface, Middle; Yellow damage at an edge, Weak; Not visible to the naked eye.)

Results are shown in Table 2, below.

TABLE 2

| | | | | | | Comparative |
|---|---|---|---|---|---|---|
| | Example 1 | Example 2 | Example 3 | Example 4 | Example 5 | Example 1 |
| Printing resolution | 50 | 60 | 50 | 50 | 50 | 100 |
| limit (μm) | | | | | | |
| Etching residue after | No residue | No residue | No residue | No residue | No residue | No residue |
| drying at 200° C. | | | | | | |
| Metal corrosion | Weak | Middle | Weak | Weak | Weak | Strong |

As shown in Table 2, it may be seen that the etching pastes prepared in Examples 1 to 5 realized a fine line width, exhibited excellent etching performance, and lessened effects on equipment (e.g., metal). For example, for Examples 1 and 5 (in which methylamine and ammonium carbonate were included, respectively) the etching pastes exhibited excellent properties in terms of fine line width and etching performance. On the contrary, the etching plates prepared in Comparative Example 1 exhibited high printing resolution limit and significant metal corrosion.

By way of summation and review, a metal pattern formation process using photoresist may result in a complicated manufacturing process, since a pattern may be formed via photoresist application, baking, exposure, and development. For example, a soft baking process at a particular temperature, and a hard baking process at a higher temperature than the soft baking temperature, may be needed to bake the photoresist, thereby making the process even more complicated. As a result, the pattern forming process may have high manufacturing costs, environmental contamination (due to waste photoresist contaminates), and defects caused by remaining photoresist.

Accordingly, a method of preparing an etching paste using an acid compound has been considered. However, realization of a fine line width with an etching paste prepared using an acid compound may be difficult, and reduced etching efficiency and equipment damage may also occur.

The embodiments provide an etching paste that can realize a fine line width and provide good etching performance without adversely affecting equipment.

The embodiments provide an etching paste having good etching stability.

The embodiments provide an etching paste capable of reducing a pattern forming process and facilitating formation of a pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An etching paste, comprising:
an organic binder;
phosphoric acid;
a nitrogen-containing compound; and
a solvent,
the nitrogen-containing compound including at least one selected from amine compounds represented by Formula 1 and ammonium compounds represented by Formula 2:
(R)ₙ—N—Hₘ, [Formula 1]
wherein, in Formula 1, R is a C1 to C12 alkyl group or a C6 to C12 substituted or unsubstituted aryl group; n is an integer from 1 to 3; m is an integer from 0 to 2; and n+m is 3,
(NH₄⁺)ₖX, [Formula 2]
wherein, in Formula 2, X is a carbonate anion, a hydroxide anion, or a carbamate anion, and k is 1 or 2.

2. The etching paste according as claimed in claim 1, wherein the organic binder is a water-soluble polymer.

3. The etching paste according as claimed in claim 1, wherein the organic binder includes at least one selected from the group of cellulose resins, xanthan gum, polyvinylpyrrolidone, polyvinyl alcohol, water-soluble (meth)acrylic resins, polyether-polyol, and poly(ether urea)-polyurethane.

4. The etching paste as claimed in claim 1, wherein the nitrogen-containing compound includes at least one selected from the group of methylamine, ethylamine, propylamine, butylamine, dodecylamine, benzylamine, ammonium hydroxide, ammonium carbonate, and ammonium carbamate.

5. The etching paste as claimed in claim 1, wherein a mole ratio of the nitrogen-containing compound to the phosphoric acid ranges from 1:1 to 1.5:1.

6. The etching paste as claimed in claim 1, wherein the etching paste includes:
3 to 20 wt % of the organic binder,
15 to 50 wt % of the phosphoric acid,
0.5 to 20 wt % of the nitrogen-containing compound, and
a balance of the solvent.

7. The etching paste as claimed in claim 1, further comprising: an additive selected from the group of organic acid, inorganic particles, foaming agents, surfactants, leveling agents, antifoaming agents, thickeners, thixotropic agents, plasticizers, dispersants, viscosity stabilizers, UV stabilizers, antioxidants, and coupling agents.

8. The etching paste as claimed in claim 1, wherein the etching paste has a viscosity of 5,000 cP·s to 30,000 cP·s.

9. The etching paste as claimed in claim 1, wherein the etching paste is for etching a target material on a substrate by printing the etching paste in a predetermined pattern on the target material, the target material including aluminum, ITO, or ATO.

10. A method of forming a pattern, the method comprising:
printing the etching paste as claimed in claim 1 on a substrate on which an etching target is deposited;
drying the etching paste; and
washing the etching paste with water to form a pattern.

11. The method of forming a pattern as claimed in claim 10, wherein the etching target is a metal or a metal compound.

12. The method of forming a pattern as claimed in claim 10, wherein the organic binder is a water-soluble polymer.

13. The method of forming a pattern as claimed in claim 10, wherein the organic binder includes at least one selected from the group of cellulose resins, xanthan gum, polyvinylpyrrolidone, polyvinyl alcohol, water-soluble (meth)acrylic resins, polyether-polyol, and poly(ether urea)-polyurethane.

14. The method of forming a pattern as claimed in claim 10, wherein the nitrogen-containing compound includes at least one selected from the group of methylamine, ethylamine, propyl amine, butylamine, dodecylamine, benzylamine, ammonium hydroxide, ammonium carbonate, and ammonium carbamate.

15. The method of forming a pattern as claimed in claim 10, wherein a mole ratio of the nitrogen-containing compound to the phosphoric acid ranges from 1 to 1.5.

16. The method of forming a pattern as claimed in claim 10, wherein the etching paste includes:
3 to 20 wt % of the organic binder,
15 to 50 wt % of the phosphoric acid,
0.5 to 20 wt % of the nitrogen-containing compound, and
a balance of the solvent.

17. The method of forming a pattern as claimed in claim 10, wherein the etching paste further includes an additive selected from the group of organic acid, inorganic particles, foaming agents, surfactants, leveling agents, antifoaming agents, thickeners, thixotropic agents, plasticizers, dispersants, viscosity stabilizers, UV stabilizers, antioxidants, and coupling agents.

18. The method of forming a pattern as claimed in claim 10, wherein the etching paste has a viscosity of 5,000 cP·s to 30,000 cP·s.

19. The method of forming a pattern as claimed in claim 10, wherein drying the etching paste includes heating at a temperature of 100° C. to 250° C.

20. The method of forming a pattern as claimed in claim 10, wherein printing the etching paste includes printing the paste in a predetermined pattern on the etching target.
